(19) United States
(12) Patent Application Publication
(10) Pub. No.: US 2026/0106608 A1
(43) Pub. Date: Apr. 16, 2026

(54) SYSTEMS AND METHODS FOR REDUCING ELECTRICAL STRESS OF SWITCHING DEVICE

(71) Applicant: Micron Technology, Inc., Boise, ID (US)

(72) Inventors: Christophe Vincent Antoine Laurent, Agrate Brianza (IT); Andrea MARTINELLI, Bergamo (IT)

(73) Assignee: Micron Technology, Inc., Boise, ID (US)

(21) Appl. No.: 19/327,768

(22) Filed: Sep. 12, 2025

Related U.S. Application Data
(60) Provisional application No. 63/707,720, filed on Oct. 15, 2024.

(51) Int. Cl. H03K 17/081; H03K 17/041

(52) U.S. Cl. CPC H03K 17/08104; H03K 17/04106

(57) ABSTRACT

Methods, systems, and devices for techniques of a switching device for controllably coupling a first conductive line to, or decoupling the first conductive line from, a second conductive line, is provided. The switching device includes branches of primary transistors and branches of electrical circuits. At least one branch of the one or more branches of primary transistors comprises a plurality of primary transistors connected in series. Control terminals of the plurality of primary transistors are connected together and receive a primary control signal, and the plurality of primary transistors are controllable to switch to couple the first conductive line to, or decouple the first conductive line from, the second conductive line. The plurality of electrical circuits are configured to provide gradient voltage levels between the first conductive line and the second conductive line such that drain-source voltages of the plurality of primary transistors are limited to a maximum allowable value.

### CROSS-REFERENCE TO RELATED APPLICATIONS

This application claims priority to U.S. Provisional Application No. 63/707,720, filed on Oct. 15, 2024, entitled “SYSTEMS AND METHODS FOR REDUCING ELECTRICAL STRESS OF SWITCHING DEVICE,” the content of which is incorporated by reference in its entirety for all purposes.

### TECHNICAL FIELD

This disclosure relates to one or more memory devices, and in particular to techniques for reducing electrical stress of a switching device using multi-gate transistors.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIGS. 3A-3B are circuit diagrams of prior art switching devices including a single transistor or multiple transistors connected in series.

FIG. 3C is a circuit diagram of a prior art switching device having multiple transistors connected in series.

FIG. 3D is a diagram of voltage curves of internal nodes of a prior art switching device during ramping up of a global word line.

FIG. 4 is a block diagram of an example switching device that has reduced electrical stresses at its internal nodes, in accordance with examples as disclosed herein.

FIG. 5A is a circuit diagram of an example switching device that has a capacitive bridge, in accordance with examples as disclosed herein.

FIG. 5B is a diagram of voltage curves of internal nodes of the example switching device shown in FIG. 5A during ramping up of a global word line, in accordance with examples as disclosed herein.

FIG. 5C is a diagram of curves of drain-source voltages of the transistors in the switching device shown in FIG. 5A, in accordance with examples as disclosed herein.

FIGS. 6A-6C are circuit diagrams of an example switching device that has one or more secondary transistor branches, in accordance with examples as disclosed herein.

FIG. 6D is a diagram of voltage curves of internal nodes of the example switching devices shown in FIGS. 6A-6C during ramping up of a global word line, in accordance with examples as disclosed herein.

FIG. 6E is a diagram of voltage curves of internal nodes and control terminals of the primary transistors of the example switching devices shown in FIGS. 6A-6C, during program, program verify, and read operations, in accordance with examples as disclosed herein.

FIG. 6F is a diagram of voltage curves of internal nodes and control terminals of the primary transistors of the example switching devices shown in FIGS. 6A-6C, during an erase operation, in accordance with examples as disclosed herein.

FIG. 7A is a circuit diagram of an example switching device that has gradient control signals, in accordance with examples as disclosed herein.

FIG. 7B is a diagram of voltage curves of internal nodes of the example switching devices shown in FIG. 7A during ramping up of a global word line, in accordance with examples as disclosed herein.

FIG. 7C is a diagram of voltage curves of internal nodes and control terminals of the primary transistors of the example switching devices shown in FIG. 7A, during program, program verify, and read operations, in accordance with examples as disclosed herein.

FIG. 7D is a diagram of voltage curves of internal nodes and control terminals of the primary transistors of the example switching devices shown in FIG. 7B, during an erase operation, in accordance with examples as disclosed herein.

FIG. 8 is a block diagram illustrating an example gradient control signals generation circuit, in accordance with examples as disclosed herein.

### DETAILED DESCRIPTION

A memory device can include an array of memory cells, also referred to as a memory array. A memory array may include many memory blocks. Each memory block may have many memory cells and associated word lines for accessing the memory cells. Multiple memory blocks can be connected to a global word line. In various operations of the memory device (e.g., read, program, erase), a memory block is selected from multiple memory blocks while other memory blocks are un-selected. For selecting a memory block, multiple switching devices are typically used. Each of the multiple switching devices is connected between a global word line and a respective memory block. Thus, one end of a switching device is connected to a global word line and the other end of the switching device is connected to one or more local word lines in the memory block. When a memory block is selected to perform an operation, the switching device is turned on to electrically connect the global word line with the local word lines. If a memory block is unselected, the switching device is turned off. Such a switching device is sometimes also referred to as a string driver.

In existing technologies, a switching device may be implemented with a single transistor (e.g., an NMOS transistor). When a memory block is unselected, the single-transistor switching device may experience a high electrical stress. For example, the global word line may have a voltage of 25V while the local word line in the memory block may have a voltage of 0V. As a result, the single-transistor switching device may experience a high V_{DS} (drain-source voltage) at a semiconductor junction (e.g., a p-n junction between the channel and the doped drain or source region of the transistor). For the single transistor to reliably sustain such a high electrical stress may require complex and expensive configurations of the transistor, making it inefficient and costly.

To solve this problem, existing technologies use multiple transistors connected in series, thereby reducing the drain-source voltage of each of the multiple transistors. This type of switching device, however, may only reduce electrical stress when the voltages are static (e.g., when the voltages of the global word line and local word lines do not change or reach a stable stage). The existing technologies cannot reduce or eliminate the electrical stress entirely if the voltages applied to the switching device are varying. For example, during the ramp up of a global word line, the drain source voltage of the first transistor connected to the global word line may exceed a maximum allowable voltage. Therefore, the switching device may still experience high electrical stress in dynamic conditions.

Circuit technologies described in this disclosure can reduce or eliminate the high electrical stress in both static and dynamic conditions. In one example, a capacitive bridge is connected in parallel with primary transistors in parallel, thereby providing gradient voltage levels between two conductive lines such that drain-source voltages of the plurality of primary transistors in a switching device are limited to a maximum allowable value. The internal nodes of the primary transistors in the switching device can be charged quickly through the capacitive bridge, therefore eliminating the high electrical stress under dynamic conditions. Similarly, one or more branches of secondary transistors can be connected in parallel with the primary transistors to reduce or eliminate the high electrical stress under dynamic conditions. The secondary transistors receive gradient control voltages. In some examples, one or more branches of primary transistors receive gradient control voltages directly without having secondary transistors or other circuit elements. All embodiments disclosed herein can be used to reduce or eliminate high electrical stress under dynamic and static conditions, thereby making the device more reliable.

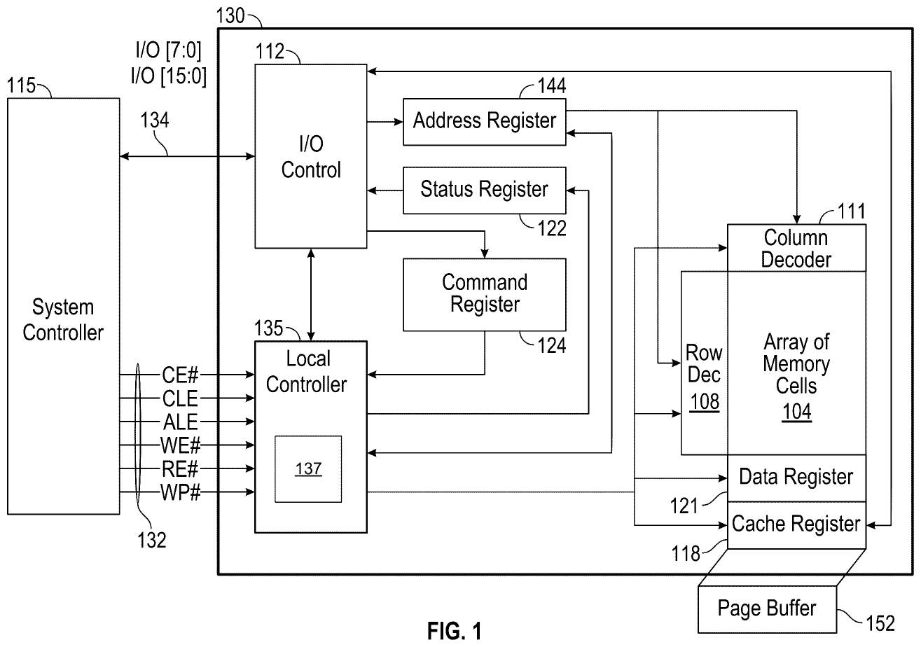

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7: 0] of I/O bus 134 at I/O control circuitry 112 and can then be written into a command register 124. The addresses can be received over input/output (I/O) pins [7: 0] of I/O bus 134 at I/O control circuitry 112 and can then be written into address register 144. The data can be received over input/output (I/O) pins [7: 0] for an 8-bit device or input/output (I/O) pins [15: 0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7: 0] for an 8-bit device or input/output (I/O) pins [15: 0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

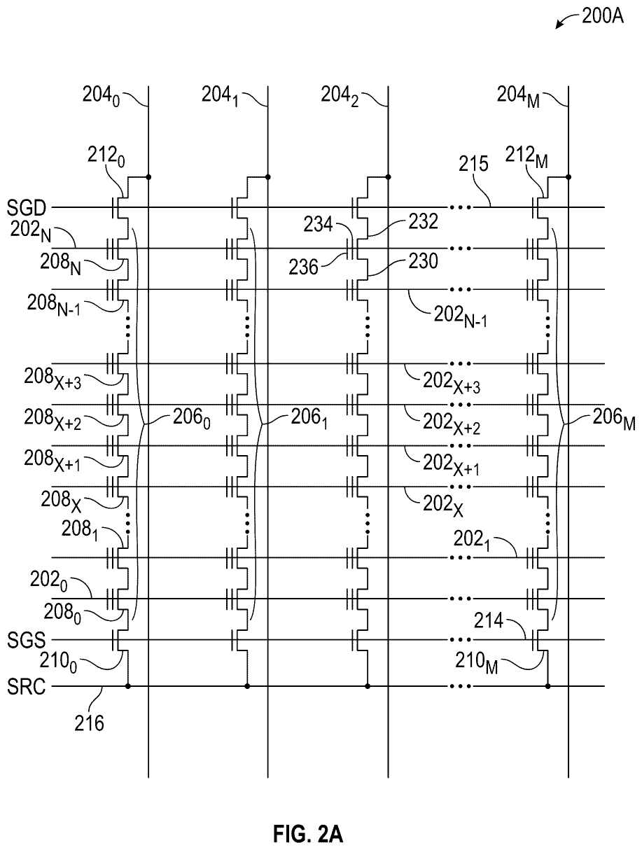

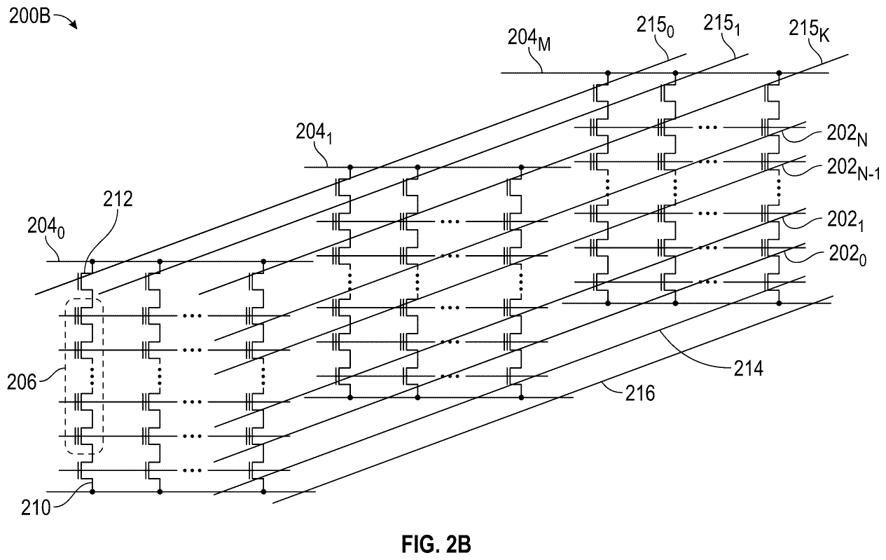

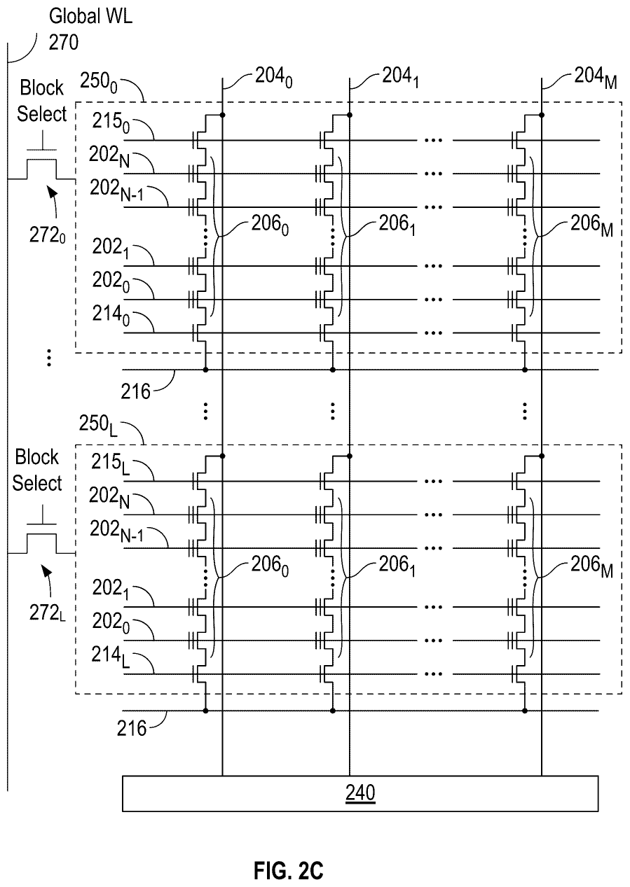

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), shown in FIG. 2C, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216.

The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

In some examples, memory blocks 250₀-250_{L} can be all connected to a global word line via switching devices 272₀-272_{L}. As shown in FIG. 2C, each block may have its own switching device 272. Each switching device 272 is individually controlled by a block select signal. In some operations of the memory device, a particular block (e.g., block 250₀) is selected while other blocks (e.g., blocks 250₁-250_{L}) are unselected. Accordingly, the a controller can turn on a switching device (e.g., 272₀) for selecting a memory block while turning off the other switching devices (e.g., 272₁-272_{L}). A switching device 272 is also referred to as a string driver.

With reference still to FIG. 2C, the bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

In some cases, concurrent operations may be performed on different memory planes. For example, concurrent operations may be performed on memory cells within different blocks 250 so long as the different blocks 250 are in different planes. In some cases, an individual memory block 250 may be referred to as a physical block, and a virtual block may refer to a group of blocks 250 within which concurrent operations may occur. For example, concurrent operations may be performed on four physical blocks of 250₀ that are within four different planes, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes may be subject to one or more restrictions, such as concurrent operations being performed on memory cells within different pages that have the same page address within their respective planes (e.g., related to command decoding, page address decoding circuitry, or other circuitry being shared across planes).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 250 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

With continued reference to FIGS. 1 and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA or Vera) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212ₘ (FIG. 2A) to be turned off to enable the drains of the select gates 212₀ to 212ₘ to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells. In some embodiments, during an erase operation, pillars inside unselected blocks are raising to a high voltage (e.g., to approximately VERA) like pillars in selected block. The difference between an unselected block and a selected block during an erase operation is that the word lines in unselected blocks are floating (while the word lines in the selected blocks are not) and then raising to approximately VERA, because they are coupled with the pillars.

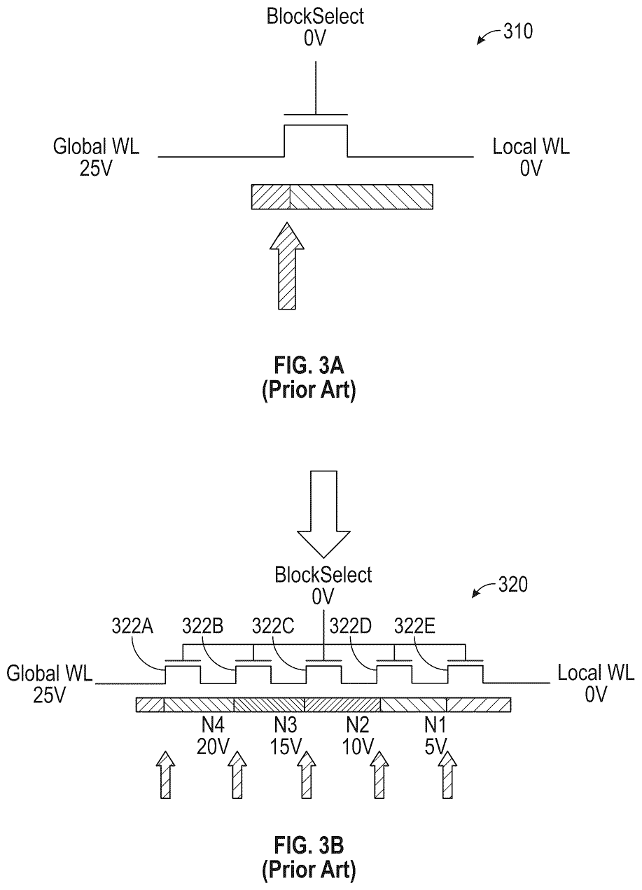

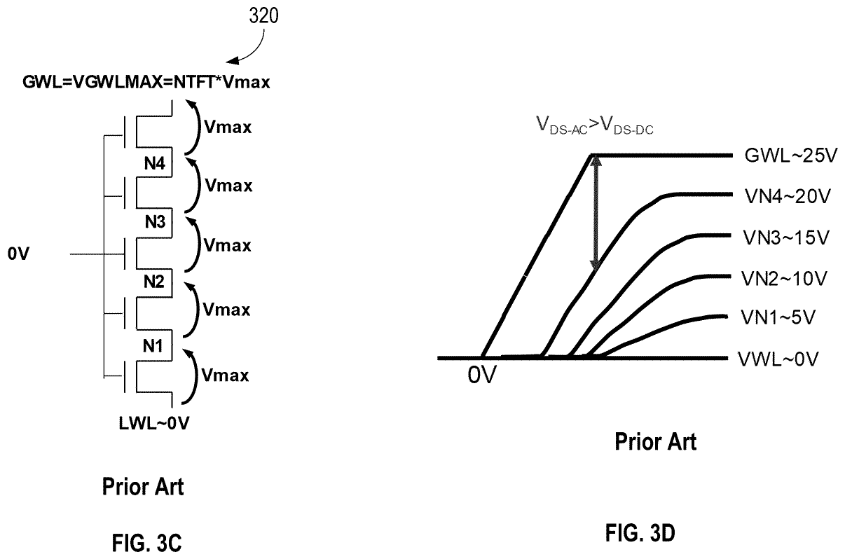

FIGS. 3A-3B are circuit diagrams of prior art switching devices including a single transistor and multiple transistors connected in series. In FIG. 3A, a switching device 310 is implemented with a single transistor (e.g., an NMOS transistor). The switching device 310 is connected between a global word line and a local word line. When a memory block is unselected, the switching device 310 may experience a high electrical stress. For example, as shown in FIG. 3A, the global word line may have a voltage of 25V while the local word line may have a voltage of 0V. As a result, the single-transistor switching device 310 may experience a high V_{DS} (drain-source voltage) at a semiconductor junction (e.g., a p-n junction between the channel (or body) and the doped drain or source region of the transistor). For the single transistor to reliably sustain such a high electrical stress may require complex and expensive configurations of the transistor, making it inefficient and costly.

To solve this problem, existing technologies use multiple transistors connected in series, thereby reducing the drain-source voltage of each of the multiple transistors. One example is shown in FIG. 3B. A switching device 320 includes five transistors 322A-322E connected in series. That is, the drain of transistor 322A is connected to the global word line; the source of transistor 322A is connected to the drain of transistor 322B. In turn, the source of transistor 322B is connected to the drain of the next transistor 322C, and so forth. The source of the last transistor 322E is connected to a local word line. Switching device 320 reduces the electrical stress imposed on each transistor. For example, as shown in FIG. 3B, in an ideal situation, the drain-source voltage of each transistor 322 is about 5V, which is significantly lower than the 25 V in the single-transistor switching device 310. The internal nodes N4, N3, N2, and N1 that are between two corresponding adjacent transistors 322 have voltages of 20V, 15V, 10V, and 5V, respectively. As a result, the semiconductor junction in each transistor has a much-reduced electrical stress compared to the junction of the device 310 in FIG. 3A. In FIG. 3B, the control terminals of each transistor 322 are connected together and receives the block select signal. If the switching device 320 is turned off, the block select signal may be at 0V.

Similar to FIG. 3B, FIG. 3C is a circuit diagram of a prior art switching device 320 having multiple transistors connected in series. FIG. 3C illustrates that the number of transistors in switching device 320 may be determined by the maximum allowable voltage (e.g., Vmax) across the drain and source of each transistor of the switching device 320, and the maximum difference between the global word line and the local word line (e.g., 25V).

Thus, if the particular transistors used for the switching device 320 can sustain a Vmax of about 5V, and the maximum voltage difference between the global word line and the local word line is about 25V, the number of transistors needed for the switching device 320 can be calculated as 5.

The switching device 320 can reduce the electrical stress of the transistors when the voltages applied to the switching device 320 are static (e.g., when the voltages of the global word line and local word lines do not change or reach a static state). The switching device 320, however, may not reduce or eliminate the electrical stress entirely if the voltages applied to the switching device 320 are varying. FIG. 3D is a diagram of voltage curves of internal nodes of a prior art switching device 320 during the voltage ramping up of a global word line. For example, during the voltage ramping up of the global word line, the drain-source voltage of the first transistor connected to the global word line (i.e., the voltage between the global word line and the internal node N4) may exceed a maximum allowable voltage. In FIG. 3D, for instance, during the voltage ramping up of the global word line (e.g., from 0V to 25V), the dynamic drain-source voltage V_{DC-AC} may be much more than the static drain-source voltage V_{DC-DC} (e.g., 5V) or the maximum allowable drain-source voltage of the transistor used for the switching device. In some situations, dynamic drain-source voltage V_{DC-AC} may be about, or more than, half of the voltage difference between the global word line and the local word line (e.g., it may be more than 12V). Therefore, the switching device 320 may still experience a high electrical stress in dynamic conditions (e.g., during voltage ramp up or ramp down).

The high electrical stress in the dynamic conditions is caused by the slow charging of the internal nodes of the transistors in the switching device 320. Specifically, as shown in FIG. 3C, the switching device 320 is turned off and thus the associated memory block is unselected. In this situation, the control terminal of the switching device 320 is applied a voltage of 0V (or any other voltages for turning off device 320). When the global word line ramps up from 0V to 25V, the internal nodes of the switching device 320 (e.g., N4, N3, N2, and N1) are also charged so that their voltages also ramp up. The internal nodes, however, can only be charged through drain-source leakage currents of the transistors because the transistors are turned off. Typically, the leakage current is very small (e.g., in the Pico amp range), and therefore, the charging time may be much longer compared to the ramping up time of the global word line. In other words, at certain time points during the ramping up of the voltage of the global word line, the internal nodes of the switching device 320 may still be at a very low voltage, thereby causing the large voltage difference between the drain-source of the transistors in the switching device 320.

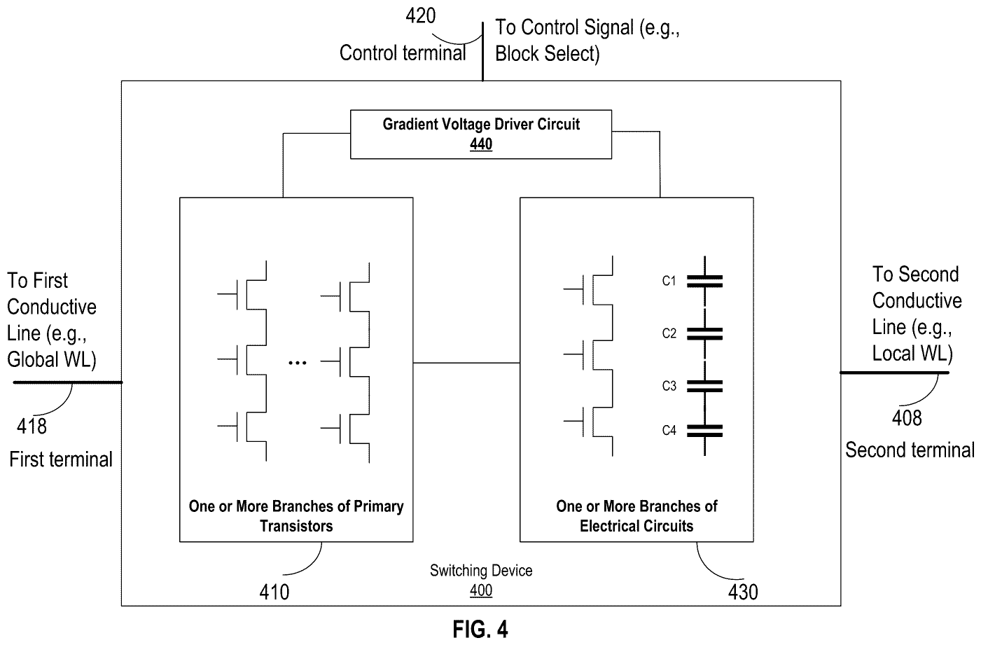

To reduce or eliminate such a high electrical stress imposed on the switching device, several circuits are described in this disclosure. FIG. 4 is a block diagram of an example switching device 400 that has reduced electrical stresses at the internal nodes of the switching device 400, in accordance with examples as disclosed herein. Switching device 400 may include one or more branches of primary transistors 410, one or more branches of electrical circuits 430, and/or a gradient voltage driver circuit 440. In some examples, switching device 400 include one or more branches of primary transistors 410 and the gradient voltage driver circuit 440 only; one or more branches of primary transistors 410 and one or more branches of electrical circuits 430 only; or all circuits 410, 430, and 440. In a preferred example, switching device 400 may not include the gradient voltage driver circuit 440, which may be a standalone circuit or a part of the other circuitry (e.g., a part of a regulator for the switching device). For instance, the gradient voltage driver circuit does not need to be included in each switching device. Instead, it can be shared by some or all the blocks in a memory plane or common to all the planes in a die.

As shown in FIG. 4, switching device 400 may have three terminals. A first terminal 418 may be connected to a first conductive line and a second terminal 408 may be connected to a second conductive line. The first and second conductive lines may be, for example, a global word line or a local word line of a memory device, respectively. However, they can also be other conductive lines including, e.g., bit lines or access lines. In other words, switching device 400 is not limited to be a string drive used with a global word line for selecting a memory block, but can also be used in any other circuits where a switching device is needed.

With continued reference to FIG. 4, switching device 400 also has a control terminal 420 connected to a control signal such as a block select signal. The control terminal 420 receives the control signal for turning on or off switching device 400. If the control signal is high, switching device 400 is turned on. The first conductive line (e.g., connected to first terminal 418) and the second conductive line (e.g., connected to second terminal 408) are electrically connected together, such that electrical signals (e.g., voltage or current signals) are communicated between the first conductive line and the second conductive line (e.g., between the global word line and a local word line). If the control signal is low, switching device 400 is turned off. Thus, there is no electrical connection between the first and second conductive lines (except possible unintended leakage currents, which are typically negligibly small). Several example embodiments of switching device 400 are described next in greater detail.

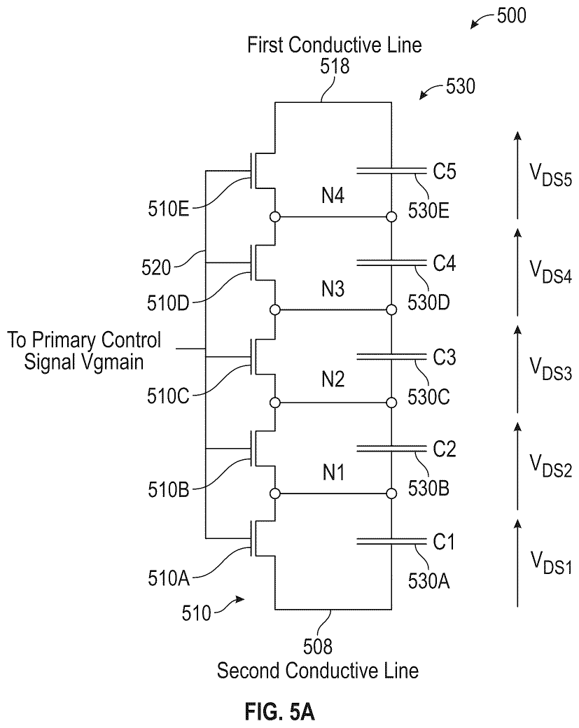

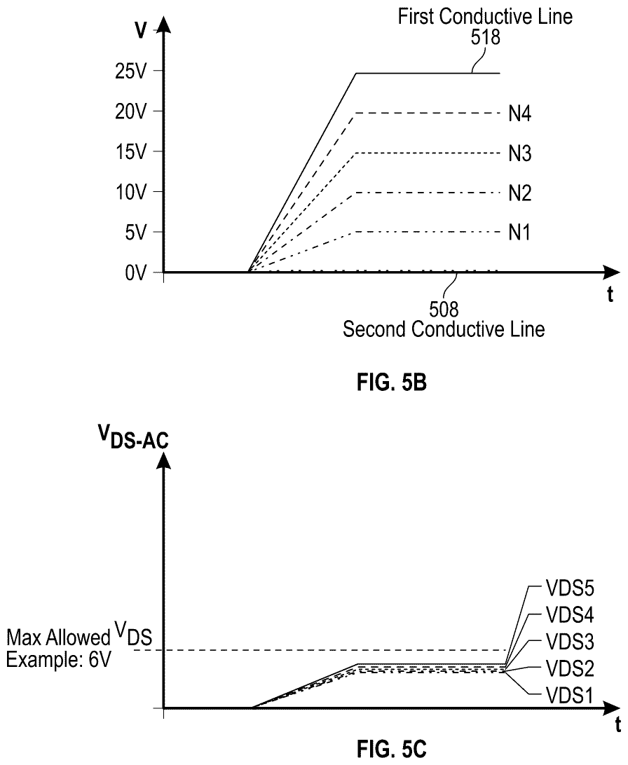

FIG. 5A is a circuit diagram of an example switching device 500 that has a capacitive bridge, in accordance with examples as disclosed herein. Switching device 500 can be used to implement the switching device 400 in FIG. 4 and the switching devices 272 in FIG. 2C. In some examples, switching device 500 includes a branch of primary transistors 510 and a branch of electrical circuit 530. As shown in FIG. 5A, the branch of primary transistors 510 comprises a plurality of primary transistors 510A-510E connected in series.

That is, a drain terminal of a primary transistor 510A is connected to the source terminal of the next primary transistor 510B, a drain terminal of the primary transistor 510B is connected to the source terminal of the next primary transistor 510C, and so forth. The source terminal of the end transistor 510A is connected to the second conductive line 508 and the drain terminal of the other end transistor 510E is connected to the first conductive line 518. The control terminal of the plurality of primary transistors 510A-510E in branch 510 are connected together and receive a primary control signal V_{gmain}. Therefore, in FIG. 5A, the control terminals of primary transistors 510A-510E are connected together and form the control terminal 520 of switch device 500, which receives the primary control signal V_{gmain}.

FIG. 5A also shows that a branch of electrical circuit 530 is used to reduce or eliminate the electrical stress of the primary transistors 510A-510E. In particular, the branch of electrical circuit 530 includes a plurality circuit elements, e.g., capacitors 530A-530E (also denoted as C1-C5). Each of capacitors 530A-530E is connected to a respective primary transistor 510A-510E in parallel. For instance, the two terminals of capacitor 530A are connected to the drain and source terminals of primary transistor 510A respectively; the two terminals of capacitor 530B are connected to the drain and source terminals of primary transistor 510B respectively, and so forth. Capacitors 530A-530E are connected in series and form a capacitive bridge. One terminal of an end capacitor 530E (e.g., C5) is connected to the first conductive line 518; and one terminal of the other end capacitor 530A is connected to the second conductive line 508. Therefore, the capacitive bridge formed by capacitors 530A-530E is coupled between the first conductive line 518 and second conductive line 508.

The capacitive bridge formed by the plurality of capacitors 530A-530E are configured to provide gradient voltage levels between the first conductive line 518 and the second conductive line 508 such that drain-source voltages of the plurality of primary transistors 510A-510E are limited to a maximum allowable value. Specifically, if the first conductive line 518 (e.g., a global word line) has a voltage of 25V and the second conductive line 508 (e.g., a local word line) has a voltage of 0V, the voltage difference between the branch of primary transistors 510 is thus 25V when the switching device 500 is turned off (e.g., the primary control signal V_{gmain} applied on the primary control terminal 520 is 0V). With the capacitive bridge 530, the capacitors 530A-530E can be charged quickly with the voltage difference. Correspondingly, the internal nodes between the primary transistors 510A-510E (e.g., nodes N1-N4) can be charged quickly by the capacitors 530A-530E. The charging of the internal nodes may thus no longer rely on the leakage current flowing through the primary transistors 510A-510E (because they are turned off). The voltages of the internal nodes N1-N4 can therefore follow the voltage changes of the first conductive line 518 during a voltage ramping up. This is illustrated more clearly in FIG. 5B.

FIG. 5B is a diagram of voltage curves of internal nodes N1-N4 of the example switching device 500 shown in FIG. 5A during ramping up of a first conductive line (e.g., a global word line), in accordance with examples as disclosed herein. As shown in FIG. 5B, because of the capacitive bridge 530, the voltages of the internal nodes N1-N4 can quickly follow the voltage of the first conductive line 518 during ramping up (e.g., changing from 0V to 25V). As described above, with only the primary transistors and no other electrical circuits (like the capacitive bridge shown in FIG. 5A), the charging of the internal nodes N1-N4 may rely only on the leakage current flowing through the primary transistors. The leakage current is very small (in the Pico amp range), and thus the internal nodes N1-N4 cannot quickly follow the change of the first or second conductive lines 518 and 508. By using the capacitive bridge 530 shown in FIG. 5A, the internal nodes N1-N4 can follow the voltages of the first and/or second conductive lines quickly during ramping up or ramping down, thereby eliminating the high electrical stress imposed to the drain-source terminals of the primary transistors 510A-510E. FIG. 5C is a diagram of curves of drain-source voltages of the primary transistors 510A-510E in the switching device 500 under dynamic conditions, in accordance with examples as disclosed herein. As shown in FIG. 5C, the drain-source voltages under dynamic conditions (denoted by V_{DS-AC}) of all primary transistors 510A-510E can be limited to values below the maximum allowable drain-source voltage (V_{DS_max}, which may be, for example, 6V).

In some examples, the capacitance of each capacitor of the plurality of the capacitors 530A-530E is dimensioned such that, during ramping up or ramping down of a voltage applied to the first conductive line 518, the drain-source voltages of the primary transistors 510A-510E are limited to the maximum allowable value (e.g., 6V). For instance, the capacitance of each of the capacitors 530A-530E is configured to be larger than the capacitance of the internal nodes N1-N4, but smaller than the capacitance of the second conductive line 508 (e.g., the local word line). Configuring the capacitance in this manner can enable the charging of the internal nodes N1-N4 quickly to follow the ramping up or ramping down of the first conductive line 518 (e.g., in real time or with minor delays that does not cause high electrical stress exceeding the allowable value). At the same time, the capacitances of capacitors 530A-530E do not add significantly parasitic capacitance to the local word line to avoid increasing (or avoid significantly increasing) the overall ramping up or ramping down time of the second conductive line 508 when the switching device 500 is turned on. In one example, the choice of the capacitance value can follow the following rules: 1) any of the capacitors C1-C5 need to be much smaller (e.g., more than 10 times smaller) of the local word line capacitance. Otherwise, the added capacitance may cause a significant delay in voltage ramping on local word line on the selected blocks. 2) any of the capacitors C1-C5 need to be much bigger (e.g., 10 times bigger) compared to parasitic capacitance at the corresponding internal nodes N1-N4 and the surrounding biased nets. Biased nets include any electrical nodes connected to a voltage source. The electrical nodes may be coupled with the N1-N4 nodes of the capacitor ladder comprising capacitors C1-C5, thereby adding stray capacitances that may affect the voltage biases of the N1-N4 nodes. For example, the above and below tiers (e.g., the above and below rows of memory cells) of a selected tier in a selected block may be biased at a voltage different from the selected tier (e.g., a selected row of memory cells). In some examples, each of the N1-N4 internal nodes in a selected tier can be coupled with its corresponding node in the below and/or above tier of the selected block. The amount of the coupling capacitance is a function of geometry (e.g., the node's physical size) and materials used.

If the capacitance values of the capacitors C1-C5 do not satisfy the above-described rules, the capacitive ladder (e.g., formed by C1-C5) may not work properly and split the high voltage on the global word line. When the capacitance value of each of capacitors C1-C5 is chosen accordingly to be with this range described above, the smaller the capacitance value the better, because the areas of the capacitors and their values impact the load (and in turn the power and performance) of the global word lines (in particular because of all unselected blocks). A selected block does not affect much the load since terminals of capacitors C1-C5 are shorted by the switching devices which are turned on when the block is selected. It is understood that in FIG. 5A, while the branch of primary transistors 510 shows that there are five primary transistors, any number of primary transistors can be used (e.g., 2, 3, 4, 5, 6, etc.). The number of primary transistors depends on the possible maximum voltage difference to which the switching device is exposed and the characteristics of the transistor (e.g., width, length, material, etc.). Similarly, any number of capacitors can be used (not limited to five) for the capacitors forming the branch of electrical circuit 530. Moreover, while one branch of primary transistors 510 is shown, more branches can be used (as described below). Similarly, multiple branches of the capacitors can be used for the branch of electrical circuits 530.

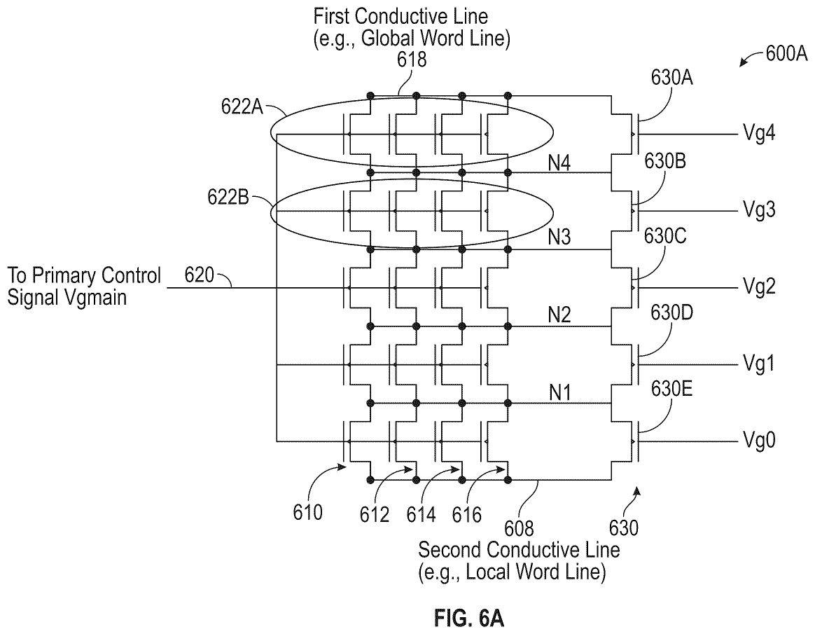

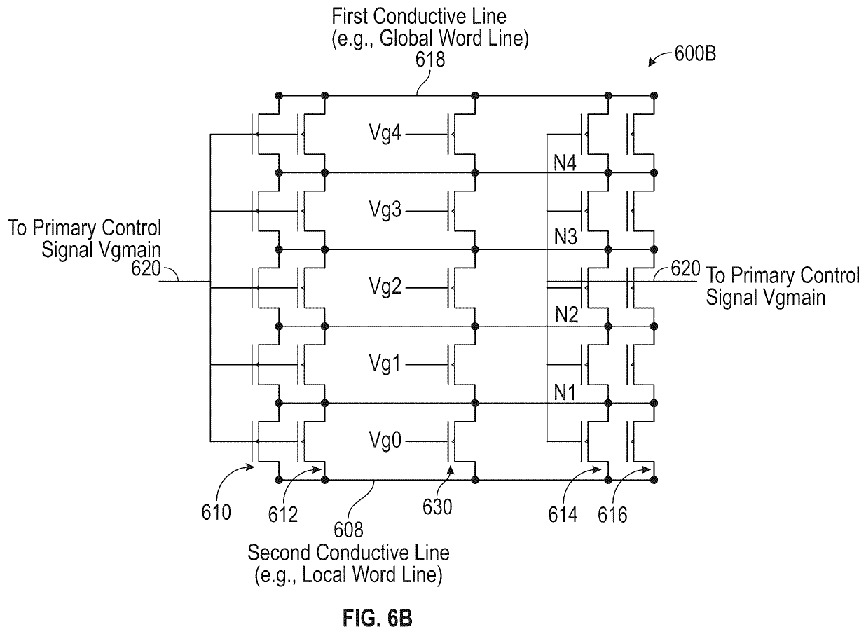

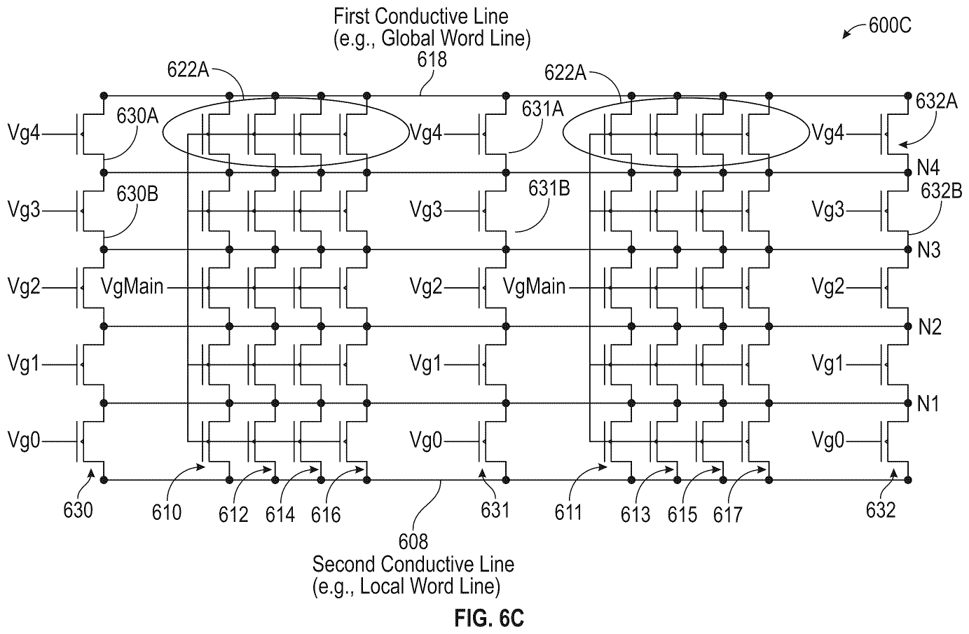

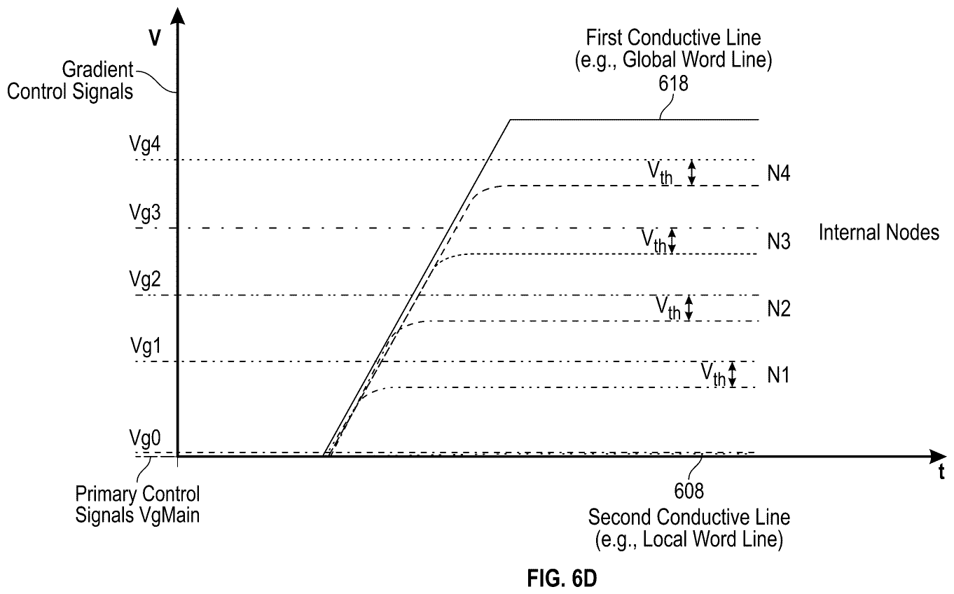

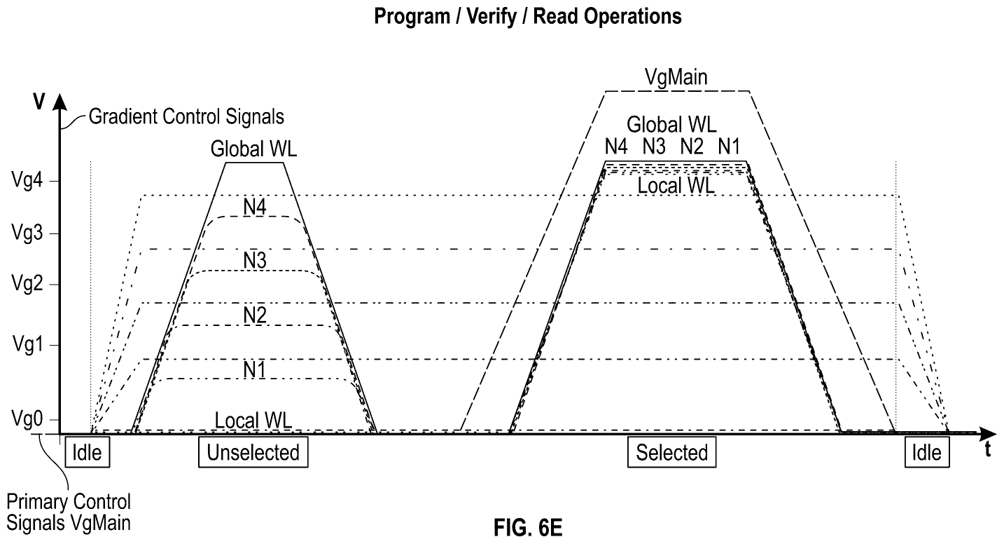

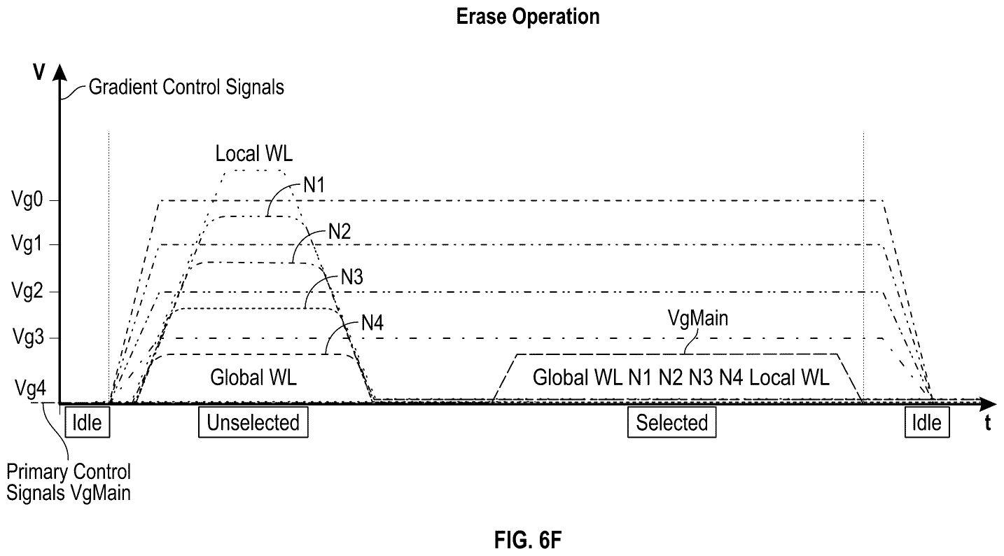

FIGS. 6A-6C are circuit diagrams of other example switching devices 600A-600C that has one or more secondary transistor branches used as the electrical circuits for reducing or eliminating high electrical stress imposed on the primary transistors, in accordance with examples as disclosed herein. Turning first to FIG. 6A, in this embodiment, there are multiple branches of primary transistors 610, 612, 614, and 616. Each of the branches of the primary transistors 610, 612, 614, and 616 shown in FIG. 6A has a plurality of primary transistors connected in series, which can be substantially the same or similar to those in the branch of primary transistors 510 described above. Each of the branches of the primary transistors 610, 612, 614, and 616 shown in FIG. 6A is coupled between the first conductive line 618 and the second conductive line 608 in parallel. Moreover, corresponding primary transistors across multiple branches of primary transistors 610, 612, 614, and 616 are connected in parallel and form multiple groups of corresponding primary transistors. As shown in FIG. 6A, for instance, the primary transistors across all branches 610, 612, 614, and 616 that are all directly connected to the first conductive line 618 form a group 622A. Within group 622A, the primary transistors are connected in parallel. Similarly, the primary transistors in the next group 622B are connected in parallel. And other groups of primary transistors can be formed similarly across the branches of primary transistors 610, 612, 614, and 616.

Switching device 600A in FIG. 6A also includes a branch of electrical circuit 630. As shown, branch of electrical circuit 630 includes a branch of secondary transistors 630A-630E connected in series. And the secondary transistors 630A-630E are connected between the first conductive line 618 and second conductive line 608. Each secondary transistor of the branch of the secondary transistors 630 is connected to a respective group of corresponding primary transistors 622 in parallel. For instance, the secondary transistor 630A is connected to the group of primary transistors 622A in parallel. As such, the drain of secondary transistor 630A is connected to all the drains of the primary transistors in group 622A; and the source of the secondary transistor 630A is connected to all the sources of the primary transistors in group 622A. The control terminal of the secondary transistor 630A is connected to a gradient control signal V_{g4}, not the primary control signal V_{gmain}. Similarly, secondary transistor 630B is connected to the group of primary transistors 622B in parallel and the control terminal of secondary transistor 630B is connected to another gradient control signal V_{g3}; and so forth. Therefore, as shown in FIG. 6A, the control terminals of the secondary transistors 630A-630E are each connected to a different gradient control signal (V_{g4}-V_{g0}, respectively). On the other hand, the control terminals of the multiple branches of primary transistors 610, 612, 614, and 616 are all connected together to form a control terminal 620 of switching device 600A. Control terminal 620 receives the primary control signal V_{gmain}. Thus, the multiple branches of primary transistors 610, 612, 614, and 616 can be turned on or off depending on the primary control signal V_{gmain}.

The operation of the switching device 600A is described next with reference to both FIG. 6A and FIG. 6D. FIG. 6D is a diagram of voltage curves of internal nodes N1-N4 of the example switching device 600A (and also devices 600B and 600C, which are described below) shown in FIG. 6A during ramping up of a first conductive line 618 (e.g., a global word line), in accordance with examples as disclosed herein. For purpose of illustration and simplicity, the global word line and first conductive line may be used interchangeably herein; and the local word line and the second conductive line may be used interchangeably here. It is understood, however, that the first and second conductive lines can be, but are not necessarily, global word line and local word line, respectively. In FIG. 6D, the horizontal axis represents the time t, and the vertical axis represents the voltage value V. As shown in FIGS. 6A and 6D, the control terminal 620 of switching device 600A receives the primary control signal V_{gmain}. If the switching device 600A is to be turned off (or remaining off), the primary control signal V_{gmain} may be at 0V. As a result, the primary transistors in the branches 610, 612, 614, and 616 are all turned off for decoupling the first conductive line 618 (e.g., the global word line) to the second conductive line 608 (e.g., the local word line). This is for the situation where the primary transistors are NMOS transistors. If they are PMOS transistors, the primary control signal V_{gmain} should have a voltage high enough to turn off the PMOS transistors.

Turning to the operation of the secondary transistors 630A-630E shown in FIG. 6A, each of these secondary transistors 630A-630E receives a gradient control signal V_{g4}-V_{g1} at its control terminal (e.g., the gate terminal of the transistor). As shown in FIGS. 6A and 6D, a first gradient control signal V_{g0} is applied to the control terminal of secondary transistor 630E; a second gradient control signal V_{g1} is applied to the control terminal of secondary transistor 630D; and so forth. In this manner, the gradient control signals V_{g0}-V_{g4} are applied to a respective secondary transistor 630E-630A. As shown in FIG. 6D, the gradient control signals V_{g0}-V_{g4} can be configured to have different voltage values that gradually increase. As one example, assuming that there are five secondary transistors 630A-630E as shown in FIG. 6A and the voltage difference between the first conductive line 618 and second conductive line 608 is 25V, the voltage value of first gradient control signal V_{g0} is set to be approximately equal to that of the primary control signal V_{gmain} (e.g., V_{g0} and V_{gmain} are both approximately at 0V). The voltage values of the gradient control signal V_{g1}, V_{g2}, V_{g3}, and V_{g4} may be set to be approximately 5V, 10V, 15V, and 25V, respectively. Because the gradient control signal V_{g0} applied on the control terminal (e.g., the gate) of secondary transistor 630E is at 0V, the secondary transistor 630E is turned off. As a result, the whole branch of the secondary transistors 630 is also turned off, isolating the first conductive line 618 from second conductive line 608 (therefore the switching device 600A remains turned off when the primary control signal V_{gmain} is low). On the other hand, the other gradient control signals Vg1-Vg4 are set at different values that are about a threshold voltage above the voltages of the respective internal nodes. Therefore, these secondary transistors may be configured to operate at the border region of being turned on or off (e.g., barely turned on or barely turned off). As a result, these secondary transistors can create a cascading voltage limitation to each of the internal nodes N1-N4 and therefore limiting the drain-source voltage of the corresponding primary transistors in the respective group (e.g., 622A, 622B, etc.). In the meantime, because these secondary transistors 630A-630D are at the border region of being turned on or off, they can conduct current much faster than just leakage current. As a result, the internal nodes N1-N4 can be charged quickly. Therefore, the secondary transistors 630A-630E reduce or eliminate the high electrical stress even under dynamic conditions (e.g., ramping up the first conductive line 618) while keeping the switching device 600A turned off (when the primary control signal V_{gmain} and the V_{g0} are both low for turning, or keeping, the switching device 600A off).

FIG. 6E is a diagram of voltage curves of internal nodes N1-N4, the primary control signal V_{gmain} for controlling the primary transistors, and the gradient control signals V_{g0}-V_{g4} for controlling the secondary transistors of the example switching devices 600A shown in FIG. 6A, during program, program verify, and read operations, in accordance with examples as disclosed herein. The left side of FIG. 6E shows the voltage curves when a memory block is unselected such that the switching device 600A is turned off. The right side of the FIG. 6E shows the voltage curves if a memory block is selected such that the switching device 600A is turned on. In FIG. 6E, the horizontal axis represents time t, and the vertical axis represents voltage value V. In FIG. 6E, for illustration purpose and simplicity, a global word line is used as an example of the first conductive line 618 of switching device 600A; a local word line is used as an example of the second conductive line 608; and a switching device 600A is used for selecting and unselecting a memory block. The switching device 600A is being operated during programming, program verify, and read operations of the memory block.

With reference to both FIGS. 6A and 6E, during a program, program verify, or read operation, for an unselected memory block (i.e., the switching device 600A is turned off or remains off), the global word line ramps from, for example, 0V to 25V; and the gradient control signals V_{g0}-V_{g4} are applied to the secondary transistors 630E-630A, respectively. The first gradient control signal V_{g0} is set at 0V, same as the primary control signal V_{gmain}. Therefore, the primary transistors in branches 610, 612, 614, and 616 are turned off, and the secondary transistor 630E (which receives the V_{g0} at its control terminal) is also turned off. As a result, the global word line is not electrically connected to the local word line (except through some negligible leakage current path), thereby isolating the global word line from the local word line. As a result, the program/verify/read operations are not performed at the unselected memory block.

As described above in FIG. 6A, the other gradient control signals V_{g1}-V_{g4} are applied to the other secondary transistors 630D-630A, respectively. The gradient control signals V_{g1}-V_{g4} are set at approximately a threshold voltage Vₜₕ above the voltage of the internal nodes N1-N4. Therefore, these secondary transistors 630D-630A may be configured to operate at the border of being turned on or off (e.g., barely turned on or barely turned off). As a result, these secondary transistors can create a cascading voltage limitation to each of the internal nodes N1-N4 and therefore limiting the drain-source voltages of the corresponding primary transistors in the respective group (e.g., 622A, 622B, etc.). In the meantime, because they operate at the border region of being turned on or off, they can conduct current much faster than if there is only the leakage current. As a result, they can charge the internal nodes N1-N4 much faster. Therefore, during the program/verify/read operation, the secondary transistors 630A-630E reduce or eliminate the high electrical stress even under dynamic conditions (e.g., when global word line ramps up) while keeping the switching device 600A turned off (when the primary control signal V_{gmain} is low, or remaining low, for turning the device 600A off). In FIG. 6E, when the global word line voltage ramps down from, for example, 25V to 0V, the voltages of the internal nodes N1-N4 also ramp down to 0V. As such, the drain-source voltages of all the transistors (primary or secondary) are at 0V or have no or minimum difference.

Turning to the right side of the FIG. 6E, during the program/verify/read operations, if a memory block is selected for performing such operations, the primary control signal V_{gmain} may ramp up from, for example 0V to a certain voltage value greater than 25V. The global word line may also ramp up from, for example, 0V to 25V. The gradient control signals V_{g0}-V_{g4} remain the same as those when the memory block is unselected. In other words, the gradient control signals V_{g0}-V_{g4} do not need to be changed regardless of whether the memory block is selected or not. Because the primary control signal V_{gmain} is ramped up to a high value, the primary transistors in the branches 610, 612, 614, and 616 of switching device 600A are all turned on. Therefore, the switching device 600A is turned on to select the memory block and to electrically connect the global word line to the local word line. In other words, the voltage of the local word line ramps up from, for example, 0V to approximately 25V (or about the same as the global word line less any drain-source voltage drops due to the primary transistors of switching device 600A). The internal nodes N1-N4 are also pulled up to a high voltage level (e.g., approximately 25V less any drain-source voltage drops due to the primary transistors of switching device 600A). As such, when a memory block is selected and the switching device 600A is turned on during program, program verify, or read operations, there is no or minimum drain-source voltage differences for all the primary transistors in switching device 600A, even under the dynamic conditions (e.g., when the global word line ramps up). Similarly, there are no or minimum voltage differences for the secondary transistors 630. Accordingly, there is no or minimum electrical stress imposed on the switching device 600A.

FIG. 6F is a diagram of voltage curves of internal nodes N1-N4, the primary control signal V_{gmain} for controlling the primary transistors, and the gradient control signals V_{g0}-V_{g4} for the secondary transistors of the example switching devices 600A shown in FIG. 6A, during the erase operation, in accordance with examples as disclosed herein. The left side of FIG. 6F shows the voltage curves when a memory block is unselected such that the switching device 600A is turned off. The right side of FIG. 6F shows the curves if a memory block is selected such that the switching device 600A is turned on. Both the left side and the right side of FIG. 6F show voltage curves of various signals and internal nodes during the erase operation. Thus, some of the signals may have opposite voltage values compared to those in the program, program verify, or read operations. For instance, during an erase operation, if a memory block is unselected, the voltage of the global word line stays at 0V, while the local word line ramps up to a sufficiently high value (e.g., 25V). These values are opposite to the voltage values of the global word lines and local word lines during program, program verify, or read operations.

In FIG. 6F, the horizontal axis represents time t, and the vertical axis represents voltage value V. In FIG. 6F, for illustration purpose and simplicity, a global word line is used as an example of the first conductive line 618 of switching device 600A; a local word line is used as an example of the second conductive line 608; and a switching device 600A is used for selecting and unselecting a memory block. The switching device 600A is being operated during an erase operation of the memory block.

With reference to both FIGS. 6A and 6F, during an erase operation, for a memory block that is unselected (i.e., the switching device 600A is turned off), the local word line ramps from, for example, 0V to 25V. The gradient control signals V_{g0}-V_{g4} are applied to the secondary transistors 630E-630A, respectively. However, compared to FIG. 6E, the voltage values of the gradient control signals V_{g0}-V_{g4} used in the erase operation are changed (e.g., reversed compared to those used for the program/verify/read operations shown in FIG. 6E). Specifically, during the erase operation, the gradient control signal V_{g4} is set at 0V, same as the primary control signal V_{gmain}. Therefore, because the primary control signal V_{gmain} is set at 0V, the primary transistors in branches 610, 612, 614, and 616 of switching device 600A are turned off, and the secondary transistor 630A is also turned off. As a result, the local word line is not electrically connected to the global word line (except through some negligible leakage current path), thereby isolating the local word line from the global word line. As a result, the erase operation is not performed at the unselected memory block.

As described above in FIG. 6A, the other gradient control signals V_{g0}-V_{g3} are applied to the other secondary transistors 630E-630B, respectively. As shown in FIG. 6E, the gradient control signals V_{g0}-V_{g3} are set at approximately a threshold voltage Vₜₕ above the voltages of the internal nodes N1-N4. Therefore, these secondary transistors 630E-630B may be configured to operate at the border region of being turned on or off (e.g., barely turned on or barely turned off). As a result, these secondary transistors 630E-630B can create a cascading voltage limitation to each of the internal nodes N1-N4 and therefore limiting the drain-source voltages of the corresponding primary transistors in the respective group (e.g., 622B and other corresponding groups). In the meantime, because the secondary transistors 630E-630B are configured to operate at the border region of being turned on or off, they can conduct current much faster than just using the leakage current. As a result, the internal nodes N1-N4 can be charged quickly under dynamic conditions (e.g., when the local word line ramps up). Therefore, during the erase operation, the secondary transistors 630A-630E reduce or eliminate the high electrical stress even under the dynamic conditions while keeping the switching device 600A turned off (when the primary control signal V_{gmain} is low for turning the device 600A off). In FIG. 6F, when the local word line voltage ramps down from, for example, 25V to 0V, the voltages of the internal nodes N1-N4 also ramp down to approximately 0V. As such, after the local word line voltage ramps down, the drain-source voltages of all the transistors (primary or secondary) are at approximately 0V or have no difference.

Turning to the right side of the FIG. 6E, during the erase operation, if a memory block is selected for performing an erase operation, the primary control signal V_{gmain} may ramp up from, for example 0V to a certain voltage value high enough to turn on the primary transistors. The gradient control signals V_{g0}-V_{g4} all remain the same as those when the memory block is unselected. In other words, the gradient control signals V_{g0}-V_{g4} do not need to be changed regardless of whether the memory block is selected or not. Because the primary control signal V_{gmain} is ramped up to a sufficiently high value for erase operation, the primary transistors in branches 610, 612, 614, and 616 of switching device 600A are all turned on. The gradient control signal V_{g4} is also ramped up to turn on the secondary transistor 630A. Therefore, the switching device 600A is turned on to select the memory block and to electrically connect the global word line to the local word line. Thus, during an erase operation, the voltages of the local word line and the global word line are both at 0V.

The internal nodes N1-N4 are also pulled down to 0V. As such, when a memory block is selected and the switching device 600A is turned on during an erase operation, there is no or minimum drain-source voltage differences for all the primary transistors in switching device 600A. Similarly, there are no or minimum voltage differences for the secondary transistors 630. Accordingly, there is no or minimum electrical stress imposed on the primary or secondary transistors in switching device 600A.

With reference back to FIG. 6B, it illustrates another example switching device 600B. Device 600B is substantially the same as device 600A shown in FIG. 6A, except that the branch of secondary transistors 630 are physically placed between the plurality of branches of primary transistors 610, 612, 614, and 616. In particular, in FIG. 6A, the branch of secondary transistors 630 in switching device 600A is physically placed on one side (e.g., the right side) of the branches of the primary transistors 610, 612, 614, and 616. Physical locations of the primary transistors and the secondary transistors refer to their locations in a physical layout on a photomask or a semiconductor chip. In FIG. 6B, the branch of second transistors 630 is physically placed in the middle of the overall physical layout of the switching device 600B (e.g., the branch 630 is placed in the middle with two branches of primary transistors on both sides). Such a physical placement of the branch of secondary transistors 630 further reduces the resistance of the conductive lines or connections between the transistors, and thus improves the current distribution within switching device 600B. The primary control signal V_{gmain}, the gradient control signals V_{g0}-V_{g4}, and voltage curves of the switching device 600B during program/verify/read/erase operations can be substantially the same as those described above with respect to device 600A (e.g., described in connection with FIGS. 6D-6F), and thus are not repeatedly described.

FIG. 6C illustrates another example switching device 600C. Compared to device 600A or 600B, device 600C comprises a plurality of branches of the secondary transistors (e.g., three such branches 630, 631, and 632 are illustrated). Similar to device 600A and 600B, in device 600C, each branch of the plurality of branches of the secondary transistors comprises a plurality of secondary transistors connected in series. Corresponding secondary transistors across the plurality of branches of secondary transistors are connected in parallel and form multiple groups of corresponding secondary transistors. Each group of the multiple groups of secondary transistors is connected to a respective group of primary transistors in parallel. For instance, as shown in FIG. 6C, secondary transistor 630A, 631A, and 632A in branches 630, 631, and 632, respectively, form a first group of secondary transistors. The first group of secondary transistors is connected in parallel with the group of primary transistors 622A. Other secondary transistors can form similar groups and connect with respective groups of the primary transistors, as shown in FIG. 6C.

In some examples, the multiple groups of secondary transistors are configured to receive gradient control signals V_{g0}-V_{g4} having different voltage levels for each group of the multiple groups of secondary transistors. For example, the first group of secondary transistors comprising transistors 630A, 631A, and 632A receives the gradient control signal V_{g4} at the control terminals. The next group of secondary transistors 630B, 631B, and 632B receives the gradient control signal V_{g3} at the control terminals, and so forth. The physical layout of the switching device 600C can be configured such that the plurality branches of the secondary transistors (630, 631, and 632) and the plurality of branches of primary transistors (610-617) are physically interleaved. As shown in FIG. 6C, the branch of secondary transistors 630 is placed physically at the left most side, the branches of primary transistors 610, 612, 614, and 616 are placed to the right side of the branch of secondary transistors 630; the branch of secondary transistors 631 is placed to the right side of the branches of primary transistors 610, 612, 614, and 616; and so forth. Physically interleaving of the secondary and primary transistor branches can reduce the resistance of the conductive lines or connections between the transistors, and thus improves the current distribution within switching device 600C. It may also enhance the reliability of switching device 600C by using more branches. The primary control signal V_{gmain}, the gradient control signals V_{g0}-V_{g4}, and voltage curves of the switching device 600C during program/verify/read/erase operations can be substantially the same as those described above with respect to device 600A (e.g., described in connection with FIGS. 6D-6F), and thus are not repeatedly described. For example, in device 600C, the primary control signal V_{gmain} is connected to all primary transistors; and the gradient control signals V_{g0}-V_{g4} are connected to respective secondary transistors in the branches 630, 631, and 632, as shown in FIG. 6C.

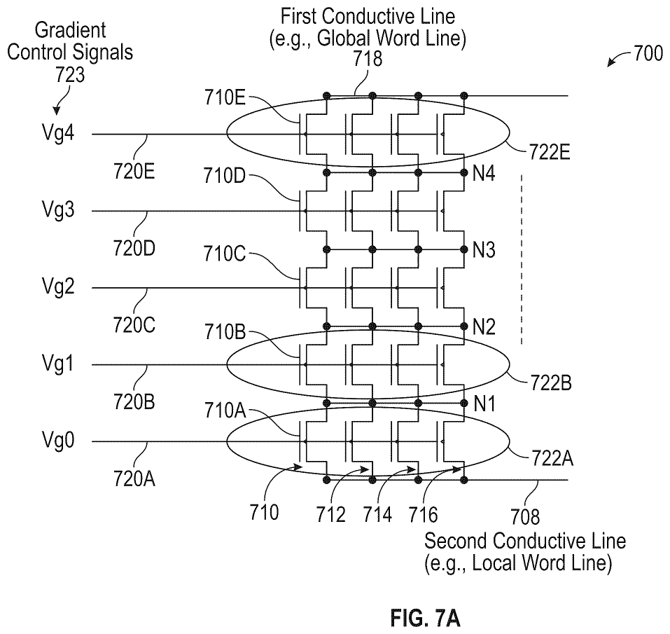

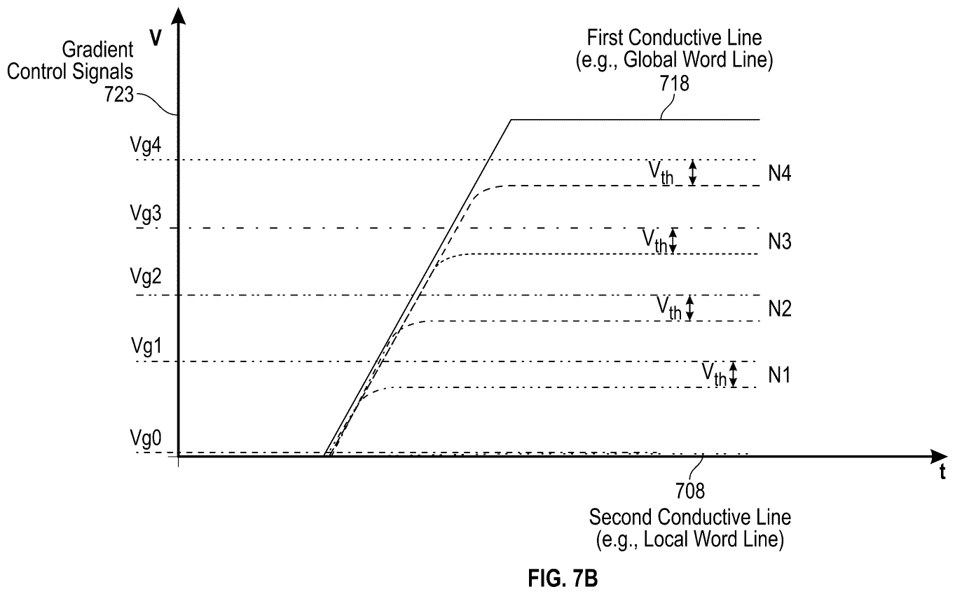

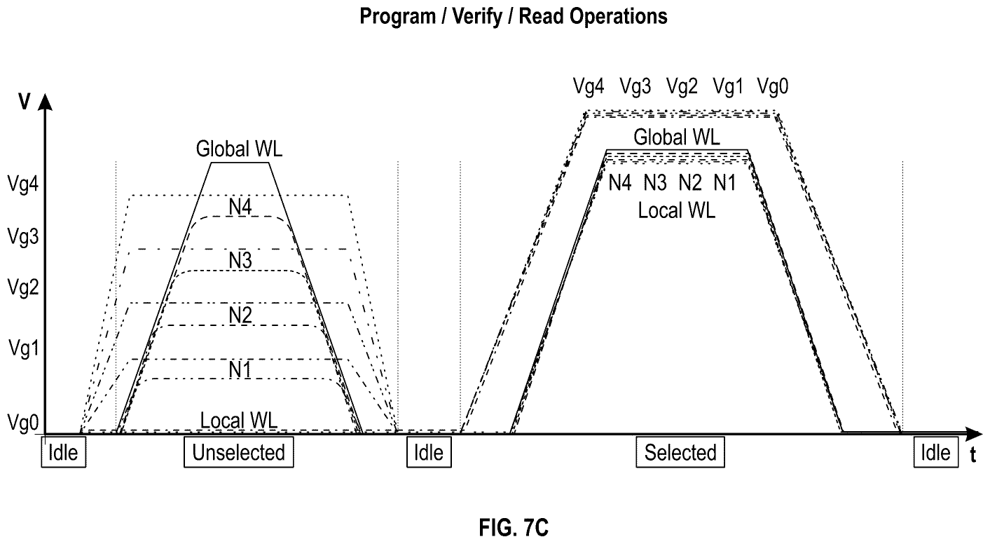

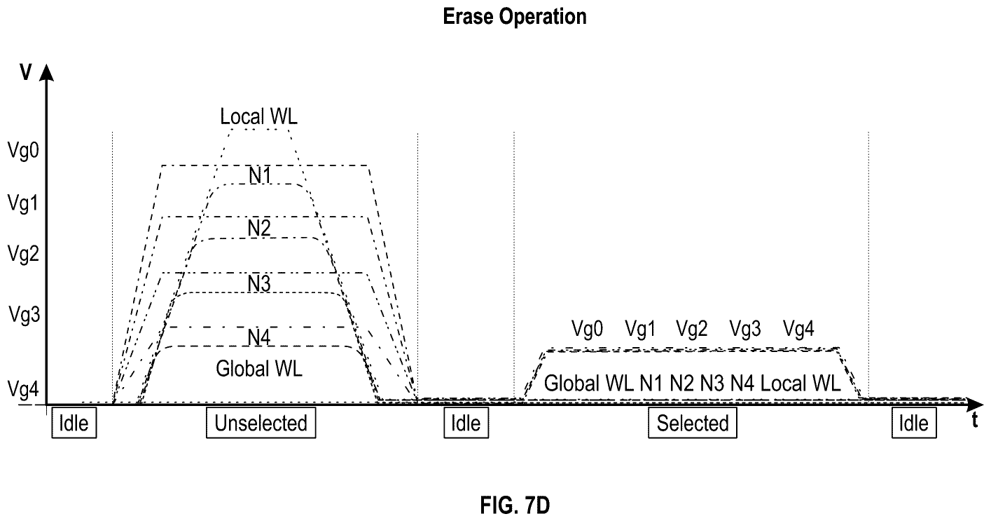

FIG. 7A is a circuit diagram of an example switching device 700 that receives gradient control signals 723, in accordance with examples as disclosed herein. Switching device 700 can be configured to include multiple branches of primary transistors 710, 712, 714, and 716, which are substantially the same as branches of primary transistors 610, 612, 614, and 616 of switching device 600A described above. The differences between switching device 700 and switching device 600A are that (1) switching device 700 does not include any secondary transistors or capacitive bridge; and (2) switching device 700 does not receive a primary control signal for all the primary transistors, but rather receive gradient control signals 723 (e.g., Vg0-Vg4).

In particular, switching device 700 shown in FIG. 7A is configured for controllably connecting a first conductive line 718 (e.g., a global word line of a memory block) to, or decoupling the first conductive line 718 from, a second conductive line (e.g., the local word line of a memory block). The switching device 700 comprises a plurality of branches of primary transistors 710, 712, 714, and 716. Similar to switching device 600A, each branch of the plurality of branches of primary transistors 710, 712, 714, and 716 comprises a plurality of primary transistors connected in series. Using branch 710 as an example, it includes five primary transistors 710A-710E connected in series (e.g., a drain terminal of one transistor may be connected to a source terminal of the next transistor in the branch, the source terminal of the first primary transistor 710A is connected to second conductive line 708, and the drain terminal of the last primary transistor 710E is connected to the first conductive line 718).

With reference still to FIG. 7A, corresponding primary transistors across the plurality of branches of primary transistors 710, 712, 714, and 716 are connected in parallel and form multiple groups of corresponding primary transistors 722A, 722B, . . . 722E. This is also substantially the same as switching device 600A shown in FIG. 6A. Unlike switching device 600A, however, control terminals of the multiple groups of primary transistors 710A-710E in switching device 700 are configured to receive gradient control signals 720A-720E (e.g., V_{g0}-V_{g4}), instead of a primary control signal V_{gmain}. As shown in FIG. 7A, the control terminals of primary transistors in group 722A receive the gradient control signal V_{g0}; the control terminals of primary transistors in group 722B receive the gradient control signal V_{g1}; and so forth.

The operations and the voltage curves associated with various terminals/nodes of switching device 700 are described next using FIGS. 7A and 7B. FIG. 7B is a diagram of voltage curves of internal nodes N1-N4 of the example switching device 700 shown in FIG. 7A during ramping up of a global word line, in accordance with examples as disclosed herein. For purpose of illustration and simplicity, the global word line and first conductive line may be used interchangeably herein; and the local word line and the second conductive line may be used interchangeably here. It is understood, however, that the first and second conductive lines can be, but are not necessarily, global and local word lines, respectively. With reference to FIG. 7B, the horizontal axis represents the time t, and the vertical axis represents the voltage value V. As shown in FIGS. 7A and 7B, unlike the switching device 600A, the control terminals 720A-720E of switching device 700 receives the gradient control signals 723 (e.g., V_{g0}-V_{g4}). In other words, the different groups of primary transistors (e.g., 722A and 722B) receive different gradient control signals 723.

Each of these groups of primary transistors (e.g., 722A-722E) receives a different gradient control signal 723 (e.g., V_{g0}-V_{g4}) at its respective control terminal 720 (e.g., the gate terminal of the transistor). As shown in FIGS. 7A and 7B, a first gradient control signal V_{g0} is applied to the control terminals 720A of the group of primary transistors 722A; a second gradient control signal V_{g1} is applied to the control terminals 720B of the group of primary transistors 722B; and so forth. In this manner, the gradient control signals V_{g0}-V_{g4} are applied to a respective group of primary transistors 722 in device 700. The gradient control signals V_{g0}-V_{g4} have different voltage values that gradually increase. As one example, assuming there are five primary transistors as shown in FIG. 7A and the voltage difference between the first conductive line 718 and second conductive line 708 is 25V, the voltage value of first gradient control signal V_{g0} is set to be about 0V. The voltage values of the gradient control signal V_{g1}, V_{g2}, V_{g3}, and V_{g4} may be set to be approximately 5V, 10V, 15V, and 25V. Because the gradient control signal V_{g0} applied on the control terminals 720A (e.g., the gates) of the first group of primary transistors 722A is at 0V, the first group of primary transistors 722A is turned off. As a result, each of the branches of the primary transistors 710, 712, 714, and 716 is also turned off, isolating the first conductive line 718 from second conductive line 708 (therefore the switching device 700 is turned off).

On the other hand, with reference to FIG. 7B, the other gradient control signals V_{g1}-V_{g4} are set at different values that are about a threshold voltage (Vₜₕ) above the voltages of the respective internal nodes N1-N4. Therefore, these groups of primary transistors 722B-722E receiving the gradient control signals V_{g1}-V_{g4} may be configured to operate at the border of being turned on or off (e.g., barely turned on or barely turned off). As a result, these groups of primary transistors (e.g., groups 722B-722E in FIG. 7A) can create a cascading voltage limitation to each of the internal nodes N1-N4 and therefore limiting the drain-source voltages of the corresponding primary transistors in the respective group (e.g., 722A, 722B, etc.). In the meantime, because the these groups of primary transistors 722B-722E operate at the border of being turned on or off, they can conduct current much faster than if there is only leakage current. As a result, the internal nodes N1-N4 can charge up quickly under the dynamic conditions (e.g., when the global word line ramps up). Therefore, the branches of primary transistors 710, 712, 714, and 716, under the control of the gradient control signals, reduce or eliminate the high electrical stress while keeping the switching device 700 turned off (when the first gradient control signal V_{g0} is low for turning the device 700 off).

FIG. 7C is a diagram of voltage curves of internal nodes N1-N4 and the gradient control signals V_{g0}-V_{g4} for the groups of primary transistors of the example switching device 700 shown in FIG. 7A, during program, program verify, and read operations, in accordance with examples as disclosed herein. The left side of FIG. 7C shows the voltage curves when a memory block is unselected such that the switching device 700 is turned off. The right side of FIG. 7C shows the curves if a memory block is selected such that the switching device 700 is turned on. In FIG. 7C, the horizontal axis represents time t, and the vertical axis represents voltage value V. In FIG. 7C, for illustration purpose and simplicity, a global word line is used as an example of the first conductive line 718 of switching device 700; a local word line is used as an example of the second conductive line 708; and a switching device 700 is used for selecting and unselecting a memory block. The switching device 700 is being operated during programming, program verify, and read operations of the memory block.

With reference to both FIGS. 7A and 7C, during a program, program verify, or read operation, for an unselected memory block (e.g., the switching device 700 is turned off), the global word line ramps from, for example, 0V to 25V, the gradient control signals V_{g0}-V_{g4} are applied to the respective groups of primary transistors 722A-722E, respectively. The first gradient control signal V_{g0} is set at 0V. Therefore, the group of primary transistors 722A in branches 710, 712, 714, and 716 are turned off. As a result, the global word line is not electrically connected to the local word line (except through some negligible leakage current path), thereby isolating the global word line from the local word line. As a result, the program/verify/read operations are not performed at the unselected memory block.

As described above in FIG. 7A, the other gradient control signals V_{g1}-V_{g4} are applied to the other groups of primary transistors 722B-722E, respectively. The gradient control signals V_{g1}-V_{g4} are set at approximately a threshold voltage Vₜₕ above the respective voltages of the internal nodes N1-N4. Therefore, these groups of primary transistors 722B-722E may be configured to operate at the border of being turned on or off (e.g., barely turned on or barely turned off). As a result, these secondary transistors can create a cascading voltage limitation to each of the internal nodes N1-N4 and therefore limiting the drain-source voltages of the corresponding primary transistors in the respective group (e.g., 722A, 722B, etc.). In the meantime, the groups of primary transistors 722B-722E operate at the border region of being turned on or off, therefore can conduct current much faster than if there is only leakage current. As a result, they can charge the internal nodes N1-N4 quickly. Therefore, during the program/verify/read operation, the groups of primary transistors 722A-722E reduce or eliminate the high electrical stress while keeping the switching device 700 turned off (when the first gradient control signal V_{g0} is low for turning the device 700 off). In FIG. 7C, when the global word line voltage ramps down from, for example, 25V to 0V, the voltages of the internal nodes N1-N4 also ramp down to 0V. As such, the drain-source voltages of all the groups of primary transistors are at 0V or have no difference. In turn, there is no electrical stress applied to these primary transistors.

Turning to the right side of the FIG. 7C, during the program/verify/read operations, if a memory block is selected for performing such operations, the global word line may ramp up from, for example, 0V to 25V. The gradient control signals V_{g0}-V_{g4} can also ramp up to a sufficiently high voltage (e.g., >25V). The local word line may also be ramped up to e.g., 25V or substantially the same as the global word line. The gradient control signals V_{g0}-V_{g4} may be set at voltage(s) that are higher than the voltage of the local word line by more than a threshold voltage (e.g., Vₜₕ). As such, the primary transistors in the branches 710, 712, 714, and 716 of switching device 700 are all turned on. Therefore, the switching device 700 is turned on to select the memory block and to electrically connect the global word line to the local word line. In other words, the voltage of the local word line ramps up from, for example, 0V to approximately 25V (or about the same as the global word line less any drain-source voltage drops due to the primary transistors of switching device 700). The internal nodes N1-N4 are also pulled up to a high voltage level (e.g., approximately 25V, less any drain-source voltage drops due to the primary transistors of switching device 700). As such, when a memory block is selected and the switching device 700 is turned on during program, program verify, or read operations, there is no or minimum drain-source voltage differences for all the primary transistors in switching device 700. Accordingly, there is no or minimum electrical stress imposed on the primary or secondary transistors in switching device 700. Applying gradient control signals V_{g0}-V_{g4} directly to primary transistors can therefore also reduce or eliminate the electrical stress without using secondary transistors or other circuit elements like capacitors.

FIG. 7D is a diagram of voltage curves of internal nodes N1-N4, and the gradient control signals V_{g0}-V_{g4} for the primary transistors of the example switching devices 700 shown in FIG. 7A, during the erase operation, in accordance with examples as disclosed herein. The left side of FIG. 7D shows the voltage curves when a memory block is unselected and the switching device 700 is turned off. The right side of the FIG. 7D shows the voltage curves if a memory block is selected and the switching device 700 is turned on. Both the left side and the right side of FIG. 7D show voltage curves of various signals and internal nodes during an erase operation. Thus, some of the signals may have opposite voltage values compared to those in the program, program verify, or read operations. For instance, during an erase operation, if a memory block is unselected, the voltage of the global word line stays at 0V, while the voltage of the local word line ramps up to a sufficiently high value (e.g., equal to or greater than 25V). These values are opposite to the voltage values of the global word lines and local word lines during program, program verify, or read operations.

In FIG. 7D, the horizontal axis represents time t, and the vertical axis represents voltage value V. In FIG. 7D, for illustration purpose and simplicity, a global word line is used as an example of the first conductive line 718 of switching device 700; a local word line is used as an example of the second conductive line 708; and a switching device 700 is used for selecting and unselecting a memory block. The switching device 700 is being operated during an erase operation of the memory block.

With reference to both FIGS. 7A and 7D, during an erase operation, for a memory block that is unselected (i.e., the switching device 700 is turned off), the local word line ramps from, for example, 0V to 25V. The gradient control signals V_{g0}-V_{g4} are applied to the control terminals 720A-720E of the groups of primary transistors 722A-722E, respectively. However, compared to FIG. 7C, the voltage values of the gradient control signals V_{g0}-V_{g4} used in the erase operation are changed (e.g., reversed to those used for the program/verify/read operations shown in FIG. 7C). Specifically, during the erase operation, the gradient control signal V_{g4} is set at 0V. Therefore, because the gradient control signal V_{g4} is set at 0V, the group of primary transistors 722E in branches 710, 712, 714, and 716 of switching device 700 are turned off. As a result, the global word line is not electrically connected to the local word line (except through some negligible leakage path), thereby isolating the local word line from the global word line. As a result, the erase operation is not performed at the unselected memory block.

As described above in FIG. 7A, the other gradient control signals V_{g0}-V_{g3} are applied to the other groups of primary transistors 722A-722D, respectively. The gradient control signals V_{g0}-V_{g3} are set at approximately a threshold voltage Vₜₕ above the respective voltages of the internal nodes N1-N4. Therefore, these groups of primary transistors 722A-722D may be configured to operate at the border region of being turned on or off (e.g., barely turned on or barely turned off). As a result, these groups of primary transistors 722A-722D can create a cascading voltage limitation to each of the internal nodes N1-N4 and therefore limiting the drain-source voltages of the primary transistors in the respective groups (e.g., 722A, 722B, etc.). In the meantime, the groups of primary transistors 722A-722D operate at the border regions of being turned on or off, therefore can conduct current much faster than if there is only leakage current. As a result, the internal nodes N1-N4 can charge up quickly under dynamic conditions (e.g., when the local word line ramps up). Therefore, during the erase operation, the groups of primary transistors 722A-722E, with predetermined gradient control signals V_{g0}-V_{g4}, reduce or eliminate the high electrical stress while keeping the switching device 700 turned off (when the gradient control signal V_{g4} is low for turning the device 700 off). In FIG. 7D, when the local word line voltage ramps down from, for example, 25V to 0V, the voltages of the internal nodes N1-N4 also ramp down to 0V. As such, after the local word line voltage ramps down, the drain-source voltages of all the primary transistors are at 0V or have no difference. Thus, there is no or minimum electrical stress after the local word line ramps down.

Turning to the right side of the FIG. 7D, during the erase operation, if a memory block is selected for performing an erase operation, the gradient control signals V_{g0}-V_{g4} all ramps up to a sufficiently high value (e.g., greater than the Vₜₕ above the source voltages of the respective groups of the primary transistors 722A-722E) to turn on the respective groups of the primary transistors 722A-722E in the branches 710, 712, 714, and 716 of switching device 700. Therefore, the switching device 700 is turned on to select the memory block and to electrically connect the global word line to the local word line. During an erase operation, the voltage of the global word line is set at 0V, thereby rendering the local word line also at approximately 0V. The internal nodes N1-N4 are also pulled down to 0V. As such, when a memory block is selected and the switching device 700 is turned on during an erase operation, there is no or minimum drain-source voltage differences for all the primary transistors in switching device 700. FIG. 7D therefore illustrates that, during an erase operation, the drain-source voltages of the plurality of primary transistors in each of branches 710, 712, 714, or 716 are limited to a maximum allowable value, regardless of whether the memory block is selected or not.

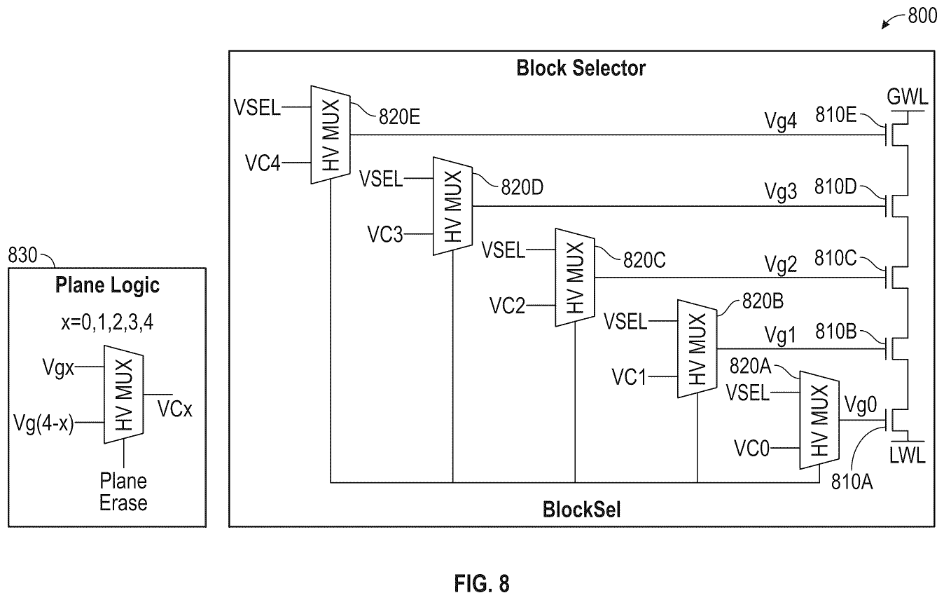

The above examples use gradient control signals for controlling the voltages applied to the control terminals of the primary transistors or secondary transistors of a switching device. FIG. 8 is a block diagram illustrating an example gradient control signals generation circuit 800, in accordance with examples as disclosed herein. The gradient control generation circuit 800 can be used for generating the gradient control signals V_{g0}-V_{g4} for controlling primary transistors (e.g., those in switching device 700 shown in FIGS. 7A-7D) as described above. The gradient control signals generation circuit 800, in some examples, includes a plurality of multiplexers 820A-820E (also referred to as MUXs 820A-820E). Each of the multiplexers 820A-820E has two inputs and one output. For example, MUX 820A has two inputs V_{C0} and V_{SEL}, and one output V_{g0}; MUX 820B has two inputs V_{C1} and V_{SEL}, and one output V_{g1}; and so forth. Each MUX 820 also has a mux control signal (e.g., BlockSel) configured to control which input should be passed to the output. For instance, if the gradient control signals V_{g0}-V_{g4} are to be provided to transistors 810A-810E in a switching device, the control signal BlockSel can be set to a first value (e.g., high) such that the signals V_{c0}-V_{c4} are passed onto the outputs of the MUXs 820A-820E, respectively. The signals V_{c0}-V_{c4} then become the gradient control signals V_{g0}-V_{g4}, respectively (see FIGS. 6D, 6E, 6F, 7C, and 7D). Transistors 810A-810E can be any of the primary transistors or secondary transistors described above that receive the gradient control signals V_{g0}-V_{g4}. If the mux control signal BlockSel is set to a second value (e.g., low), the other input signal V_{SEL} of MUXs 820A-820E can be passed onto the outputs. The input signal V_{SEL} can be set at any desired values. For instance, it can be set to a value that sufficiently high (e.g., greater than the voltage of the global word line) during a program/verify/read/erase operation, for turning on all the transistors (primary or secondary) for a selected memory block (see FIGS. 7C and 7D).

The above description related to the gradient control generation circuit 800 can be used for generating the gradient control signals V_{g0}-V_{g4} for controlling primary transistors (e.g., those in switching device 700 shown in FIGS. 7A-7D). Similar circuits can be configured to control the secondary transistors (e.g., those in switching device 600A-600C shown in FIGS. 6A-6F) as described above. For instance, for switching device 600A-600C, the gradient control signals V_{gx} (e.g., V_{g0}-V_{g4} signals) for controlling secondary transistors can be generated similarly (e.g., equal to the V_{Cx} outputs) using plane logic 830, while the V_{gmain} signal can be provided by a single multiplexer (not shown) driven by the “BlockSel” signal. The single multiplexer has two inputs including a VSEL value on a selected block and voltage ground (GND) or in any case a lower voltage available on unselected blocks.

It is understood that the circuitry represented in the block selector of FIG. 8 represents a conceptual circuit which can be used to drive the gates of the switching transistors in the arrangement shown in FIG. 7A. The other arrangements shown in other figures can be driven by similar circuitry. For example, they may need only an unique gate control signal for each of the switching transistors ranging from a voltage greater than the global word line voltage when a block is selected to 0V when the block is unselected. The plane logic 830 shown in FIG. 8 represents an example multiplexer circuit used to swap the gate voltage of the secondary transistors in the arrangement shown in FIG. 6A between the erase biasing and all the other conditions. Thus, when the block is under an erase operation, the multiplexer of plane logic 830 can be set to receive a gate voltage for each of the secondary transistors 630A-630E shown in FIG. 6A; and when the block is under another operation (e.g., program/read/verify, etc.), the multiplexer of plane logic 830 can be set to receive a different gate voltage for each of the secondary transistors 630A-630E shown in FIG. 6A.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate. In the above description, the primary transistors and/or the secondary transistors may be complementary metal-oxide-semiconductor (CMOS) type transistors. In other embodiments, the primary transistors and/or the secondary transistors may be thin-film transistors (TFTs). Compared to a planar CMOS transistor, a single TFT transistor may be more difficult to sustain a high voltage and thus require using the technologies described above (e.g., using multiple TFTs with gradient controls, capacitor ladders, etc.). Moreover, for TFT transistors, the series of many transistors may not be as area demanding as the planar CMOS transistors. For example, the series of TFT transistors may be fabricated in a vertical direction (z-direction) or with dedicated layers built over a CMOS silicon wafer.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A switching device for controllably coupling a first conductive line to, or decoupling the first conductive line from, a second conductive line, the switching device comprising:
one or more branches of primary transistors, wherein:
at least one branch of the one or more branches of primary transistors comprises a plurality of primary transistors connected in series,
control terminals of the plurality of primary transistors are connected together and receive a primary control signal, and
the plurality of primary transistors are controllable to switch, based on the primary control signal, to couple the first conductive line to, or decouple the first conductive line from, the second conductive line; and
one or more branches of electrical circuits, wherein:
at least one branch of the one or more branches of electrical circuits comprises a plurality of circuit elements connected in series, and
each circuit element of the plurality of circuit elements is connected to a respective primary transistor in parallel, and
the plurality of circuit elements are configured to provide gradient voltage levels between the first conductive line and the second conductive line such that drain-source voltages of the plurality of primary transistors are limited to a maximum allowable value.

2. The switching device of claim 1, wherein:
the first conductive line is a global word line of a memory device;
the second conductive line is a local word line of a memory block in the memory device; and
the one or more branches of primary transistors couple between the global word line and the local word line.

3. The switching device of claim 1, wherein:
the plurality of circuit elements connected in series forms a capacitive bridge comprising a plurality of capacitors connected in series, and
the capacitive bridge is coupled between the first conductive line and the second conductive line.

4. The switching device of claim 3, wherein:
each capacitor of the plurality of capacitors is coupled to a corresponding primary transistor of the plurality of primary transistors in parallel.

5. The switching device of claim 4, wherein capacitance of each capacitor of the plurality of capacitors is dimensioned such that, during ramping up or ramping down of a voltage applied to the first conductive line, the drain-source voltages of the plurality of primary transistors are limited to the maximum allowable value.

6. The switching device of claim 4, wherein the capacitance of each capacitor of the plurality of capacitors is:
bigger than capacitance of a corresponding internal node between two neighboring primary transistors of the plurality of primary transistors; and
smaller than capacitance associated with the second conductive line.

7. The switching device of claim 1, wherein:
the one or more branches of primary transistors comprise a plurality of branches of primary transistors;
corresponding primary transistors across the plurality of branches of primary transistors are connected in parallel and form multiple groups of corresponding primary transistors;
the one or more branches of electrical circuits comprises one or more branches of secondary transistors; and
the secondary transistors in each branch of the one or more branches of secondary transistors are connected in series.

8. The switching device of claim 7, wherein:
the one or more branches of the secondary transistors comprise a first branch of the secondary transistors;
each secondary transistor of the first branch of the secondary transistors is connected to a respective group of corresponding primary transistors in parallel; and
control terminals of the first branch of the secondary transistors are configured to receive a plurality of gradient control signals having different voltage levels for each secondary transistor of the first branch of the secondary transistors.

9. The switching device of claim 8, wherein the first branch of the secondary transistors are physically placed between the plurality of branches of primary transistors.

10. The switching device of claim 7, wherein:
the one or more branches of the secondary transistors comprise a plurality of branches of the secondary transistors;
each branch of the plurality of branches of the secondary transistors comprises a plurality of secondary transistors connected in series;
corresponding secondary transistors across the plurality of branches of secondary transistors are connected in parallel and form multiple groups of corresponding secondary transistors;
each group of the multiple groups of secondary transistors is connected to a respective group of primary transistors in parallel; and
the multiple groups of secondary transistors are configured to receive gradient control signals having different voltage levels for each group of the multiple groups of secondary transistors.

11. The switching device of claim 10, wherein the plurality branches of the secondary transistors and the plurality of branches of primary transistors are physically interleaved.

12. The switching device of claim 7, wherein the primary transistors or the secondary transistors are thin-film transistors (TFTs).

13. A switching device for controllably connecting a first conductive line to, or decoupling the first conductive line from, a second conductive line, the switching device comprising a plurality of branches of primary transistors, wherein:
each branch of the plurality of branches of primary transistors comprises a plurality of primary transistors connected in series,
corresponding primary transistors across the plurality of branches of primary transistors are connected in parallel and form multiple groups of corresponding primary transistors; and
control terminals of the multiple groups of primary transistors are configured to receive gradient control signals such that drain-source voltages of the plurality of primary transistors in each branch are limited to a maximum allowable value.

14. The switching device of claim 13, wherein:
the first conductive line is a global word line of a memory device;
the second conductive line is a local word line of a memory block in the memory device; and
the plurality of primary transistors in each branch of the one or more branches of primary transistors couples between the global word line and the local word line.

15. The switching device of claim 13, wherein the multiple groups of primary transistors comprise a first group, the control terminal of the first group of primary transistors being configured to:
receive a first control signal of the gradient control signals, and
couple the first conductive line to, or decouple the first conductive line from, the second conductive line based on the first control signal and no other control signals of the gradient control signals.

16. The switching device of claim 15, wherein the control terminals of the other groups of the multiple groups of primary transistors are configured to:
receive the other control signals of the gradient control signals, wherein the other control signals have voltage levels above the voltage levels of respective internal nodes of the primary transistors by approximately a threshold voltage.

17. The switching device of claim 13, wherein the primary transistors are thin-firm transistors (TFTs).

18. A memory device comprising:
an array of memory cells arranged in multiple memory blocks; and
a switching device for controllably coupling a first conductive line to, or decoupling the first conductive line from, a second conductive line, the switching device comprising:
one or more branches of primary transistors, wherein:
at least one branch of the one or more branches of primary transistors comprises a plurality of primary transistors connected in series,
control terminals of the plurality of primary transistors are connected together and receive a primary control signal, and
the plurality of primary transistors are controllable to switch, based on the primary control signal, to couple the first conductive line to, or decouple the first conductive line from, the second conductive line; and
one or more branches of electrical circuits, wherein:
at least one branch of the one or more branches of electrical circuits comprises a plurality of circuit elements connected in series, and
each circuit element of the plurality of circuit elements is connected to a respective primary transistor in parallel, and
the plurality of circuit elements are configured to provide gradient voltage levels between the first conductive line and the second conductive line such that drain-source voltages of the plurality of primary transistors are limited to a maximum allowable value;
wherein the switching device is configured to select a memory block and unselect one or more other memory blocks.

19. The memory device of claim 18, further comprising gradient voltage driver circuitry configured to generate gradient control signals and provide the gradient control signals to the switching device.

20. A memory system comprising:
a processor; and
a memory device coupled to the processor, the memory device comprises:
an array of memory cells arranged in multiple memory blocks; and
a switching device for controllably coupling a first conductive line to, or decoupling the first conductive line from, a second conductive line, the switching device comprising:
one or more branches of primary transistors, wherein:
at least one branch of the one or more branches of primary transistors comprises a plurality of primary transistors connected in series,
control terminals of the plurality of primary transistors are connected together and receive a primary control signal, and
the plurality of primary transistors are controllable to switch, based on the primary control signal, to couple the first conductive line to, or decouple the first conductive line from, the second conductive line; and
one or more branches of electrical circuits, wherein:
at least one branch of the one or more branches of electrical circuits comprises a plurality of circuit elements connected in series, and
each circuit element of the plurality of circuit elements is connected to a respective primary transistor in parallel, and
the plurality of circuit elements are configured to provide gradient voltage levels between the first conductive line and the second conductive line such that drain-source voltages of the plurality of primary transistors are limited to a maximum allowable value;
wherein the switching device is configured to select a memory block and unselect one or more other memory blocks.
